(19) United States
(12) Patent Application Publication
(10) Pub. No.: US 2013/0059139 A1
(43) Pub. Date: Mar. 7, 2013

(54) TRANSPARENT, WEATHER-RESISTANT BARRIER FILM HAVING AN IMPROVED BARRIER EFFECT AND SCRATCH RESISTANCE PROPERTIES

(71) Applicants: Jochen Ackermann, Muehltal (DE); Claudius Neumann, Rossdorf (DE); Ghirmay Seyoum, Egelsbach (DE); Florian Schwager, Muenster (DE)

(72) Inventors: Jochen Ackermann, Muehltal (DE); Claudius Neumann, Rossdorf (DE); Ghirmay Seyoum, Egelsbach (DE); Florian Schwager, Muenster (DE)

(73) Assignee: Evonik Roehm GmbH, Darmstadt (DE)

(21) Appl. No.: 13/697,221

(22) PCT Filed: May 31, 2011
(86) PCT No.: PCT/EP11/58889

§ 371 Date: Nov. 9, 2012

(30) Foreign Application Priority Data
Jul. 22, 2010 (DE) 10 2010 038 288.4

(51) Int. Cl. B32B 7/12; B32B 37/12; B32B 7/02; C23C 14/08; B32B 27/30; B32B 27/08

(52) U.S. Cl. 428/216; 428/522; 428/483; 428/516; 428/215; 428/448; 204/192.14; 156/326

(57) ABSTRACT

The invention relates to the production of a transparent, weather-resistant barrier film by lamination, extrusion lamination (adhesive lamination, melt lamination or hotmelt lamination) or extrusion coating. The film can also contain a scratch-resistant coating. For this purpose, two or more transparent film composites, which consist in each case of two externally disposed polyolefin or polyester layers which are in each case inorganically coated and glued to the inorganic layer on the inside, are connected to each other. Said composite is laminated with a weather-resistant, transparent film (e.g. PMMA or PMMA polyolefin coextrudate or PMMA polyester coextrudate). The inorganic oxide layers have the property of a high optical transparency while having at the same time a good barrier effect against water vapour and oxygen while the PMMA layer exhibits weather resistance stability.

### FIELD OF THE INVENTION

The invention relates to the production of a transparent, weathering-resistant barrier film by lamination, extrusion lamination (adhesive, melt or hotmelt lamination) or extrusion coating. To produce the film, two or more transparent film assemblies, each consisting of two external polyolefin layers or polyester layers, each inorganically coated and bonded to one another internally by the inorganic layer, are laminated to a weathering-resistant, transparent film (e.g. PMMA or PMMA-polyolefin coextrudate or PMMA-polyester coextrudate). The inorganic oxide layers have the property of a high optical transparency in conjunction with a good barrier effect to water vapour and oxygen, while the PMMA layer contributes the weathering stability. The film further comprises a coating which enhances the scratch resistance.

### PRIOR ART

Weathering-resistant, transparent and impact-resistant films based on polymethacrylate are sold by the applicant under the name PLEXIGLAS®. Patent DE 38 42 796 A1 describes the production of a clear, impact-resistant moulding composition based on acrylate, and describes films and mouldings produced from it, and also a process for producing the moulding compound. These films have the advantage that they do not discolour and/or embrittle on exposure to heat and moisture. Furthermore, they avoid the defect known as stress whitening when exposed to impact or flexural stress. These films are transparent and remain so even on exposure to heat and moisture, under weathering and on exposure to impact or flexural stress.

The processing of the moulding composition to give the stated transparent, impact-resistant films is accomplished ideally by extruding the melt through a slot die and smoothing it on a roller bed. Features of films of this kind are permanent clarity, insensitivity to heat and cold, weathering resistance, low yellowing and embrittlement, and low stress whitening on creasing or folding, and they are therefore suitable, for example, as windows in tarpaulins, car covers or sails. Such films have a thickness of below 1 mm, for example 0.02 mm to 0.5 mm. One important area of application lies in the formation of thin surface coats of, for example, 0.02 mm to 0.5 mm in thickness on rigid, dimensionally stable substructures, such as metal sheets, boards, chipboard panels, plastics sheets and the like. For producing such coatings, there are a variety of methods available. For instance, the film may be extruded to a moulding composition, smoothed and laminated on to the substrate. Through the technique of extrusion coating, an extruded strand can be applied to the surface of the substrate and smoothed by means of a roll. If a thermoplastic is used as the substrate itself, it is possible to coextrude both compositions to form a surface layer comprising the clear moulding composition of the invention.

The barrier properties of PMMA films to water vapour and oxygen, however, are inadequate, and yet such properties are necessary for medical applications, for applications in the packaging industry, but above all in electrical applications involving outdoor use.

For the purpose of improving the barrier properties, transparent, inorganic layers are applied to polymer films. Silicon oxide and aluminium oxide layers have become established in particular. These inorganic oxide layers (SiOₓ or AlOₓ) are applied by the vacuum coating method (chemically, JP-A-10025357, JP-A-07074378; thermal or electron-beam evaporation, sputtering, EP 1 018 166 B1, JP 2000-307136 A, WO 2005-029601 A2). EP 1018166 B1 discloses how the UV absorption of the SiOx layer can be influenced by the ratio of silicon to oxygen in the SiOx layer. This is important in order to protect underlying layers from UV radiation. The disadvantage, however, is that the change in the ratio of silicon to oxygen also alters the barrier effect. Transparency and barrier effect, therefore, cannot be varied independently of one another.

These inorganic oxide layers are applied primarily to polyesters and polyolefins, since these materials withstand the temperature stress during the evaporation procedure. Furthermore, the inorganic oxide layer adheres well to polyesters and polyolefins, the latter being subjected to a corona treatment prior to coating. Since, however, these materials are not stable to weathering, they are often laminated to halogenated films, as described in WO 94/29106, for example. Halogenated films, however, are problematic on environmental grounds.

As disclosed by U. Moosheimer, Galvanotechnik 90 No. 9, 1999, pp. 2526-2531, the coating of PMMA with an inorganic oxide layer does not improve the barrier effect to water vapour and oxygen, because PMMA is amorphous. Unlike polyesters and polyolefins, however, PMMA is stable to weathering.

The applicant, in DE 102009000450.5, uses coating materials which bring about effective adhesion between the inorganic layer and the adhesion promoter. As is known to the skilled person, the adhesion between organic and inorganic layers is more difficult to achieve than between layers which are of the same kind in this respect.

Part of the presentation by the company AlcanPackaging at the “Organic Light Emitters” conference on 25 Jun. 2008 in Basel related to multi-layer laminates comprising different, silicon oxide-coated PET films, which in turn were joined to one another by adhesive layers. For solar applications in the exterior sector, however, these laminates are too susceptible and short-lived, since they break down rapidly under UV irradiation.

### PROBLEM

The problem addressed by the present invention is that of providing a flexible photovoltaic system which has broad usefulness and is long-lived even under extreme weathering conditions.

The object addressed by the invention is therefore that of providing a barrier film for producing flexible photovoltaic systems of this kind, the barrier film being weathering-stable and highly transparent (>80% in the wavelength range >300 nm) and ensuring high barrier properties to water vapour and oxygen.

Furthermore, a partial discharge voltage of more than 1000 V is to be attained.

### SOLUTION

The problems are solved by an innovative, multiple-layer film laminate featuring a combination of an at least three-layer first laminate, comprising a PMMA layer, as support laminate, and a multiple-layer, second laminate, comprising two or more inorganic oxide layers, as barrier laminate. Support laminate and barrier laminate in turn are joined to one another by an adhesive layer.

The problem is solved in particular by a film laminate comprising a barrier laminate and a support laminate which is particularly stable to weathering. The properties are achieved by multi-layer films, the individual layers being combined with one another by vacuum vapour coating, lamination, extrusion lamination (adhesive, melt or hotmelt lamination) or extrusion coating. For this purpose, customary methods may be used, examples being those described in S. E. M. Selke, J. D. Culter, R. J. Hernandez, “Plastics Packaging”, 2nd edition, Hanser-Verlag, ISBN 1-56990-372-7 on pages 226 and 227.

In this construction, the support laminate is located on the outside of the film laminate. The barrier laminate, which is generally adhered to a substrate, is located, accordingly, between support laminate and substrate.

Support laminate and barrier laminate are joined to one another by an adhesive layer (adhesive4 hereinafter).

The first laminate, referred to below as the support laminate, is composed of an outer PMMA protective layer comprising 0.1 to 5.0% by weight, preferably 0.5 to 3.0% by weight, more preferably 2.0 to 3.0% by weight of UV stabilizer, and a second support film comprising a transparent polyester or polyolefin, preferably of PET or polypropylene. The protective layer and the support film are joined to one another in turn by an adhesive layer (hereinafter: adhesive1), preferably by a hotmelt, more preferably by a hotmelt comprising an acrylate-ethylene copolymer.

The PMMA protective layer fulfils the property of weathering stability; the support layer leads to stability on the part of the laminate. Since a direct inorganic coating of PMMA is not possible in accordance with the state of the art, the support layer is additionally required to ensure a long-lasting and firm bond to the barrier laminate, which optionally carries an inorganic layer on the surface. The PMMA layer, in turn, protects the polyester or polyolefin support film from effects of weathering.

Optionally, the PMMA protective layer is coated in turn. The coating serves to reduce surface marring and/or to improve the abrasion resistance and/or as an anti-soil coating, with a scratch-resistant coating being particularly important.

Furthermore, the function of protection from UV radiation is no longer, as in the prior art, to be undertaken by the inorganic oxide layer, but instead by the PMMA layer. Accordingly, the oxide layer can be optimized exclusively according to optical and barrier criteria.

The barrier laminate in turn is composed of at least three polymers films, examples being polyester films or polyolefin films, preferably polyester films, more preferably PET films, that are coated with an inorganic barrier layer. The inorganic barrier layer is preferably a silicon oxide layer, referred to below as SiOₓ layer. The inorganic oxide layer fulfils the barrier properties, especially in respect to atmospheric oxygen and water vapour. The at least three SiOₓ-coated films are joined to one another in turn by an adhesive, preferably a 2-component polyurethane adhesive. In this way a support laminate is formed.

The adhesive layers comprise an adhesive2, when two oxide layers are joined to one another, an adhesive3, when two of the films are joined to one another, or adhesive2a, when an oxide layer is joined to a polymer film.

For greater ease of understanding, systems based on the preferred SiOₓ-coated PET films are described below. It should be noted, however, that this provides a description only of one preferred embodiment, and the SiOₓ layer should be understood as a representative of other inorganic oxide layers, and the PET film as a representative of other polyester or polyolefin films.

The support laminate is composed of at least three and not more than eight, preferably of four or six, SiOₓ-coated PET films. These in turn are joined to one another by adhesive layers.

The sequence of the layers may vary. In one embodiment a PET film is located on the surface, i.e. on the side that is subsequently joined to the support laminate, and hence, for example, in the field of application of photovoltaics, on the side that is directed towards the sun. It is followed by an SiOₓ layer, which is followed in turn by an adhesive layer2a, which is followed in its turn by a PET film, a second SiOₓ layer and a second adhesive layer2a. All further films, up to a total of eight, are laminated in the same orientation in this exemplary embodiment.

In one preferred embodiment, the problem that frequently occurs of adhesion between inorganic and oxide layers is circumvented by bonding two inorganically coated films to one another with the inorganic side facing inwards and the organic film side pointing outwards. The latter can then easily be joined to other organic polymers, such as the bottom side of the support laminate, or a second double laminate. One particularly preferred construction for the barrier laminate, therefore, is that with the following sequence:

PET-SiOₓ-adhesive2-SiOₓ-PET-adhesive3-PET-SiOₓ-adhesive2-SiOₓ-PET.

Optionally, and hence likewise with particular preference, the system is a film system made up of six of these individual films. This produces the following sequence:

PET-SiOₓ-adhesive2-SiOₓ-PET-adhesive3-PET-SiOₓ-adhesive2-SiOₓ-PET-adhesive3-PET-SiOₓ-adhesive2-SiOₓ-PET.

Adhesion between the inorganic layers with adhesive2 may be achieved, for example, using a 2-component polyurethane-based adhesive (2K-PU adhesive) which is optimized for inorganic layers.

The PET films, or polyether or polyolefin films, may likewise be joined to one another by means of a 2K-PU adhesive, by a hotmelt adhesive, based on EVA or acrylate-ethylene, for example, or by extrusion lamination. In the latter case, the adhesive3 layers are done away with. Alternatively, a PET film may also be coated on both sides with SiOₓ. These films are laminated in turn to single-sidedly coated PET films. In this case, for the system with four SiOₓ layers for example, the resulting construction is as follows:

PET-SiOₓ-adhesive2-SiOₓ-PET-SiOₓ-adhesive2-SiOₓ-PET.

The assembly of 2 inorganically coated support layers (equipped with barrier layer) has the advantage that the two inorganic layers are protected by the two outer support layers. On lamination with the protective film, therefore, the barrier layer is not damaged. Furthermore, the adhesive used to produce the assembly can be optimized for the inorganic layer.

### DETAILED DESCRIPTION

### Advantages of the Invention

The barrier film of the invention
is particularly weathering-stable,
is halogen-free,
possesses a high barrier effect to water vapour and oxygen (<0.01 g/(m² d)),
protects underlying layers from UV radiation independently of the composition of the SiOₓ layers,
can be produced inexpensively, since a thin film can be used for the discontinuous process of inorganic vacuum vapour coating,
can be produced easily, since inorganic layers are joined only to inorganic layers, and organic layers only to organic layers,

A further feature of the film laminate of the invention is that it has a partial discharge voltage of at least 1000 V and a transparency of more than 80% in the range of more than 300 nm.

### The Support Laminate

The support laminate is composed of a support film, a protective layer, an optional scratch-resistant coating and an optional adhesive layer1. The support laminate is joined to the barrier laminate by the adhesive layer4.

### The Protective Layer

As the protective layer, and hence as the outermost layer of the first laminate, use is made of films composed preferably of polymethyl methacrylate (PMMA) or impact-resistant PMMA (im-PMMA). Alternatively, besides PMMA films, use may also be made of PVDF/PMMA two-layer films or films composed of PVDF/PMMA blends as protective layer, as already described in DE 102009000450.

The PMMA protective layer has a thickness of between 10 and 200 μm, preferably between 20 and 150 μm and more preferably between 30 and 100 μm.

The impact-modified poly(meth)acrylate plastic is composed of 20% to 80% by weight, preferably 30% to 70% by weight, of a poly(meth)acrylate matrix and 80% to 20% by weight, preferably 70% to 30% by weight, of elastomer particles having an average particle diameter of 10 to 150 nm (measurement, for example, by the ultracentrifuge method).

The impact-modified poly(meth)acrylate plastic (im-PMMA) is composed of a fraction of matrix polymers, polymerized from at least 80% by weight of units of methyl methacrylate and also, optionally, 0% to 20% by weight of units of monomers which are copolymerizable with methyl methacrylate, and of a fraction, dispersed in the matrix, of impact modifiers based on crosslinked poly(meth)acrylates.

The matrix polymer is composed more particularly of 80% to 100% by weight, preferably of 90% to 99.5% by weight, of free-radically polymerized methyl methacrylate units and optionally of 0% to 20% by weight, preferably of 0.5% to 10% by weight, of further free-radical polymerizable comonomers, examples being C₁ to C₄ alkyl(meth)acrylates, more particularly methyl acrylate, ethyl acrylate or butyl acrylate. The average molecular weight M_{w} (weight average) of the matrix is preferably in the range from 90 000 to 200 000 g/mol, more particularly 100 000 to 150 000 g/mol (M_{w} determined by means of gel permeation chromatography with reference to polymethyl methacrylate as a calibration standard). The molecular weight M_{w} can be determined, for example, by gel permeation chromatography or by scattered-light methods (see, for example, H. F. Mark et al., Encyclopaedia of Polymer Science and Engineering, 2nd Edition, Vol. 10, pages 1 ff., J. Wiley, 1989).

Preference is given to a copolymer of 90% to 99.5% by weight of methyl methacrylate and 0.5% to 10% by weight of methyl acrylate. The Vicat softening temperatures VST (ISO 306-B50) may be situated in the range of at least 90° C., preferably from 95 to 112° C.

The polymethacrylate matrix preferably comprises an impact modifier, which may be, for example, an elastomer particle with a two- or three-shell construction.

Impact modifiers for polymethacrylate plastics are well known. Production and composition of impact-modified polymethacrylate moulding compositions are described in EP-A 0 113 924, EP-A 0 522 351, EP-A 0 465 049 and EP-A 0 683 028, for example.

Present in the polymethacrylate matrix are 1% to 30% by weight, preferably 2% to 20% by weight, more preferably 3% to 15% by weight, more particularly 5% to 12% by weight, of an impact modifier. The impact modifier is obtained in a conventional way by a bead polymerization or by emulsion polymerization.

At its most simple, the impact modifier comprises crosslinked particles obtainable by means of bead polymerization and having an average size in the range from 10 to 150 nm, preferably 20 to 100, more particularly 30 to 90 nm. These particles are composed in general of at least 40%, preferably 50%-70%, by weight of methyl methacrylate, 20% to 40% by weight, preferably 25% to 35%, by weight of butyl acrylate and 0.1% to 2%, preferably 0.5% to 1%, by weight of a crosslinking monomer, an example being a polyfunctional (meth)acrylate such as allyl methacrylate, for example, and optionally of further monomers such as, for example, 0% to 10%, preferably 0.5% to 5%, by weight of C₁-C₄ alkyl methacrylates, such as ethyl acrylate or butyl methacrylate, preferably methyl acrylate, or other vinylically polymerizable monomers such as styrene, for example.

Preferred impact modifiers are polymer particles which may have a two-layer or three-layer core-shell construction and are obtained by emulsion polymerization (see, for example, EP-A 0 113 924, EP-A 0 522 351, EP-A 0 465 049 and EP-A 0 683 028). For the purposes of the invention, however, suitable particle sizes for these emulsion polymers must lie within the range from 10 to 150 nm, preferably 20 to 120 nm, more preferably 50 to 100 nm.

A three-layer or three-phase construction with one core and two shells may be of the following type: an innermost (hard) shell may be composed substantially, for example, of methyl methacrylate, small fractions of comonomers, such as ethyl acrylate, for example, and a crosslinker fraction, e.g. allyl methacrylate. The middle (soft) shell may be constructed, for example, of butyl acrylate and optionally styrene, while the outermost (hard) shell substantially corresponds, usually, to the matrix polymer which produces compatibility with and effective attachment to the matrix. The polybutyl acrylate fraction in the impact modifier is critical for the impact resistance effect and is situated preferably in the range from 20% to 40% by weight, more preferably in the range from 25% to 35% by weight.

In the extruder, the impact modifier and matrix polymer may be mixed in the melt to give impact-modified polymethacrylate moulding compositions. The extruded material is generally first pelletized. The pellets may be processed further by extrusion or injection moulding to form mouldings such as sheets or injection-moulded parts.

Preferably, especially for film production, but not restricted thereto, use is made of a system which is known in principle from EP 0 528 196 A1 and which comprises a two-phase, impact-modified polymer composed of the following:

a1) 10% to 95% by weight of a coherent hard phase having a glass transition temperature T_{g} of above 70° C., synthesized from

a11) 80% to 100% by weight (based on a1) of methyl methacrylate and

a12) 0% to 20% by weight of one or more other ethylenically unsaturated, free-radically polymerizable monomers, and

a2) 90% to 5% by weight of a tough phase which is distributed within the hard phase and has a glass transition temperature T_{g} of below −10° C., synthesized from

a21) 50% to 99.5% by weight of a C₁-C₁₀ alkyl acrylate (based on a2)

a22) 0.5% to 5% by weight of a crosslinking monomer having two or more ethylenically unsaturated, free-radically polymerizable radicals, and

a23) optionally other ethylenically unsaturated, free-radically polymerizable monomers,

with at least 15% by weight of the hard phase a1) being linked covalently with the tough phase a2).

The two-phase impact modifier can be produced by a two-stage emulsion polymerization in water, as described in DE-A 38 42 796, for example. In the first stage the tough phase a2) is produced, composed of at least 50%, preferably more than 80%, by weight of lower alkyl acrylates, thus giving a glass transition temperature T_{g} of below −10° C. for this phase. Crosslinking monomers a22) used are (meth)acrylic esters of diols, such as, for example, ethylene glycol dimethacrylate or 1,4-butanediol dimethacrylate, aromatic compounds having two vinyl or allyl groups, such as divinylbenzene, for example, or other crosslinkers having two ethylenically unsaturated, free-radically polymerizable radicals, such as allyl methacrylate as graft crosslinker, for example.

Crosslinkers having three or more unsaturated, free-radically polymerizable groups, such as allyl groups or (meth)acryloyl groups, include, for example, triallyl cyanurate, trimethylolpropane triacrylate and trimethacrylate, and pentaerythritol tetraacrylate and tetramethacrylate. Further examples in this regard are given in U.S. Pat. No. 4,513,118.

The ethylenically unsaturated, free-radically polymerizable monomers stated under a23) may be, for example, acrylic acid and/or methacrylic acid, and also their alkyl esters having 1-20 carbon atoms, it being possible for the alkyl radical to be linear, branched or cyclic. Furthermore, a23) may comprise other free-radically polymerizable aliphatic comonomers which are copolymerizable with the alkyl (meth)acrylates a21). However, significant fractions of aromatic comonomers, such as styrene, alpha-methylstyrene or vinyltoluene, are to be excluded, since they lead to unwanted properties on the part of the moulding composition A, particularly in the event of weathering.

When producing the tough phase in the first stage, precise attention must be paid to adjusting the particle size and its non-uniformity. In this context, the particle size of the tough phase is dependent substantially on the concentration of the emulsifier. The particle size may be controlled advantageously through the use of a seed latex. Particles having an average size (weight average) of below 130 nm, preferably below 70 nm, and having a particle size non-uniformity U₈₀ of below 0.5 (U₈₀ is determined from an integral evaluation of the particle size distribution as determined by ultracentrifuge, as follows: U₈₀=[(r₉₀−r₁₀)/r₅₀]−1, where r₁₀, r₅₀ and r₉₀ are the average integral particle radii for which, respectively, 10%, 50% and 90% of the particle radii are below this value and 90%, 50% and 10% of the particle radii are above this value), preferably below 0.2, are achieved with emulsifier concentrations of 0.15% to 1.0% by weight, based on the water phase. This applies especially to anionic emulsifiers, such as the particularly preferred alkoxylated and sulphated paraffins, for example. Polymerization initiators used are, for example, 0.01% to 0.5% by weight of alkali metal or ammonium peroxodisulphate, based on the water phase, and the polymerization is initiated at temperatures of 20 to 100° C. Preference is given to using Redox systems, an example being a combination of 0.01% to 0.05% by weight of organic hydroperoxide and 0.05% to 0.15% by weight of sodium hydroxymethylsulphinate, at temperatures of 20 to 80° C.

The hard phase a1), bonded covalently to an extent of at least 15% by weight with the tough phase a2), has a glass transition temperature of at least 70° C. and may be composed exclusively of methyl methacrylate. As comonomers a12) it is possible for there to be up to 20% by weight of one or more other ethylenically unsaturated, free-radically polymerizable monomers in the hard phase, with alkyl (meth)acrylates, preferably alkyl acrylates having 1 to 4 carbon atoms, being used in amounts such that the glass transition temperature is not below the figure stated above.

The polymerization of the hard phase a1) proceeds in a second stage, likewise in emulsion, using the customary auxiliaries, such as those also used, for example, for the polymerization of the tough phase a2).

In one preferred embodiment, the hard phase comprises low molecular mass UV absorbers and/or copolymerized UV absorbers in amounts of 0.1% to 10% by weight, preferably 0.5%-5% by weight, based on A, as a constituent of the comonomeric components a12) in the hard phase. Examples of the polymerizable UV absorbers, of the kind described inter alia in U.S. Pat. No. 4,576,870, include 2-(2′-hydroxyphenyl)-5-methacrylamidobenzotriazole or 2-hydroxy-4-methacryloyloxybenzophenone. Low molecular mass UV absorbers may be, for example, derivatives of 2-hydroxybenzophenone or of 2-hydroxyphenylbenzotriazole or phenyl salicylate. Generally speaking, the low molecular mass UV absorbers have a molecular weight of less than 2×10³ (g/mol). Particularly preferred are UV absorbers with low volatility at the processing temperature and with homogeneous miscibility with the hard phase a1) of the polymer A.

Use may also be made of coextrudates of polymethacrylates and polyolefins or polyesters. Coextrudates of polypropylene and PMMA are preferred. Also possible, furthermore, is a fluorinated, halogenated layer, such as, for example, a coextrudate of PVDF with PMMA or a blend of PVDF and PMMA, albeit with a loss of the advantage of absence of halogen.

The protective layer has a thickness of 20 to 500 μm; the thickness is preferably 50 to 400 μm and very preferably 200 to 300 μm.

### Light Stabilizers

In accordance with the invention it is possible for light stabilizers to be added to the support layer.

By light stabilizers are meant UV absorbers, UV stabilizers and free-radical scavengers.

UV protectants that are optionally present are, for example, derivatives of benzophenone, whose substituents such as hydroxyl and/or alkoxy groups are located usually in positions 2 and/or 4. These include 2-hydroxy-4-n-octoxybenzophenone, 2,4-dihydroxybenzophenone, 2,2′-dihydroxy-4-methoxybenzophenone, 2,2′,4,4′-tetrahydroxybenzophenone, 2,2′-dihydroxy-4,4′-dimethoxybenzophenone, and 2-hydroxy-4-methoxybenzophenone. Additionally very suitable as a UV protection additive are substituted benzotriazoles, including especially 2-(2-hydroxy-5-methylphenyl)benzotriazole, 2-[2-hydroxy-3,5-di-(alpha,alpha-dimethylbenzyl)phenyl]benzotriazole, 2-(2-hydroxy-3,5-di-tert-butylphenyl)benzotriazole, 2-(2-hydroxy-3-butyl-5-methylphenyl)-5-chlorobenzotriazole, 2-(2-hydroxy-3,5-di-tert-butylphenyl)-5-chlorobenzotriazole, 2-(2-hydroxy-3,5-di-tert-amylphenyl)benzotriazole, 2-(2-hydroxy-5-tert-butylphenyl)benzotriazole, 2-(2-hydroxy-3-sec-butyl-5-tert-butylphenyl)benzotriazole and 2-(2-hydroxy-5-tert-octylphenyl)benzotriazole, and phenol, 2,2′-methylenebis[6-(2H-benzotriazol-2-yl)-4-(1,1,3,3,-tetramethylbutyl)].

Besides the benzotriazoles it is also possible to use a UV absorber from the class of the 2-(2′-hydroxyphenyl)-1,3,5-triazines, such as, for example, phenol, 2-(4,6-diphenyl-1,2,5-triazin-2-yl)-5-(hexyloxy).

UV protectants that can be used, furthermore, are ethyl 2-cyano-3,3-diphenylacrylate, 2-ethoxy-2′-ethyloxalic bisanilide, 2-ethoxy-5-tert-butyl-2′-ethyloxalic bisanilide, and substituted benzoic acid phenyl esters.

The light stabilizers and/or UV protectants may be present as low molecular mass compounds, as indicated above, in the polyalkyl methacrylate compositions to be stabilized. It is also possible, however, for UV absorbing groups in the matrix polymer molecules to be bonded covalently, by copolymerization, with polymerizable UV absorption compounds, such as acrylic, methacrylic or allyl derivatives of benzophenone or benzotriazole derivatives, for example.

The fraction of UV protectants, which may also be mixtures of chemically different UV protectants, is generally 0.01% to 10% by weight, especially 0.01% to 5% by weight, more particularly 0.02% to 2% by weight, based on the (meth)acrylate copolymer.

Examples of free-radical scavengers/UV stabilizers here include sterically hindered amines, which are known under the name HALS (Hindered Amine Light Stabilizers). They can be used for inhibiting ageing processes in coatings and plastics, especially in polyolefin plastics (Kunststoffe, 74 (1984) 10, pp. 620 to 623; Farbe+Lack, Volume 96, 9/1990, pp. 689 to 693). Responsible for the stabilizing action of the HALS compounds is the tetramethylpiperidine group they contain. This class of compound may be both unsubstituted and also substituted by alkyl or acyl groups on the piperidine nitrogen. The sterically hindered amines do not absorb in the UV region. They scavenge free radicals formed, which is something the UV absorbers are not able to do. Examples of HALS compounds with a stabilizing action, which may also be employed in the form of mixtures, are as follows:

bis(2,2,6,6-tetramethyl-4-piperidyl) sebacate, 8-acetyl-3-dodecyl-7,7,9,9-tetramethyl-1,3-8-triazaspiro[4.5]decane-2,5-dione, bis(2,2,6,6-tetramethyl-4-piperidyl) succinate, poly(N-β-hydroxyethyl-2,2,6,6-tetramethyl-4-hydroxypiperidine-succinic ester) or bis(N-methyl-2,2,6,6-tetramethyl-4-piperidyl) sebacate.

Particularly preferred UV absorbers are, for example, Tinuvin® 234, Tinuvin® 360, Chimasorb® 119 or Irganox® 1076.

The free-radical scavengers/UV stabilizers are employed in the polymer mixtures of the invention in amounts of 0.01% to 15% by weight, especially in amounts of 0.02% to 10% by weight, more particularly in amounts of 0.02% to 5% by weight, based on the (meth)acrylate copolymer.

The UV absorber is preferably in the PMMA layer, but may also be present in the polyolefin layer or polyester layer.

The protective layer, moreover, possesses a sufficient layer thickness to ensure the partial discharge voltage of 1000 V. In the case of PMMA, for example, this is the case from a thickness of 250 μm onwards. Partial discharge voltage is the voltage at which an electrical discharge occurs which partly bridges the insulation (see DIN EN 60664-1).

### The Scratch-Resistant Coating

The term “scratch-resistant coating” is understood in the context of this invention to be a collective term for coatings which are applied for the purpose of reducing surface scratching and/or for improving the abrasion resistance. For the use of the film laminates, for example, in photovoltaic systems, a high abrasion resistance, in particular, is of great importance.

A further important property of the scratch-resistant coating in the widest sense is that this layer should not negatively alter the optical properties of the film assembly.

As a scratch-resistant coating it is possible to use polysiloxanes, such as CRYSTALCOAT™ MP-100 from SDC Techologies Inc., AS 400-SHP 401 or UVHC3000K, both from Momentive Performance Materials. These coating formulations are applied by roll coating, knife coating or flow coating, for example, to the surface of the film assembly or of the outer film.

Examples of further coating technologies contemplated include PVD (physical vapour deposition; physical gas-phase deposition) and also CVD plasma (chemical vapour deposition; chemical gas-phase deposition).

### The Support Film

As support film or, synonymously, support layer, use is made of films of preferably polyesters (PET, PET-G, PEN) or polyolefins (PE, PP). The choice of support film is determined by the following vital properties: the film must be highly transparent, flexible and resistant to distortion under heat. Films with this kind of profile of properties have proven in particular to be polyester films, especially coextruded, biaxially oriented polyethylene terephthalate (PET) films.

The support layer has a thickness of between 10 and 500 μm, the thickness being preferably between 100 and 400 μm and very preferably between 150 and 300 μm.

The support layer has a transparency of more than 80%, preferably more than 85%, more preferably more than 90% in the wavelength range of >300 nm, preferably 350 to 2000 nm, more preferably 380 to 800 nm.

### Adhesive Layer1

The PMMA protective layer and the support film are produced, depending on the combination of materials, by film coextrusion or by lamination, such as by extrusion lamination, for example. The choice of an adhesive in this case is determined by the substrates to be bonded to one another and by the exacting requirements imposed on the transparency of the adhesive layer. For the combination of PMMA and PET, melt adhesives are preferred. Examples of such melt adhesives are ethylene-vinyl acetate hotmelts (EVA hotmelts) or acrylate ethylene hotmelts. Acrylate-ethylene hotmelts are preferred. The adhesive layer1 generally has a thickness of between 10 and 100 μm, preferably between 20 and 80 μm and more preferably between 40 and 70 μm.

### The Barrier Laminate

As already stated, the barrier laminate is distinguished by a sequence of different barrier films, consisting of a polymer film provided with an inorganic barrier layer.

### The Polymer Film

Polymer films used are films of, preferably, polyolefins (PE, PP) or polyesters (PET, PET-G, PEN). Films of other polymers may also be used (for example, polyamides or polylactic acid). The support layer has a thickness of 1 to 100 μm, the thickness being preferably 5 to 50 μm and very preferably 10 to 30 μm.

The transparency of the polymer film is more than 80%, preferably more than 85%, more preferably more than 90% in the wavelength range of >300 nm, preferably 350 to 2000 nm, more preferably 380 to 800 nm.

### The Barrier Layer

The barrier layer is applied to the support layer and is composed preferably of inorganic oxides, for example SiOₓ or AlOₓ. Use may also be made, however, of other inorganic materials (for example SiN, SiNₓO_{y}, ZrO, TiO₂, ZnO, FeₓO_{y}, transparent organometallic compounds). For the precise layer construction, see the working examples. As SiOₓ layers it is preferred to use layers having a silicon to oxygen ratio of 1:1 to 1:2, more preferably 1:1.3 to 1:1.7. The layer thickness is 5 to 300 nm, preferably 10 to 100 nm, more preferably 20 to 80 nm.

In the case of AlOx, x is from a range of 0.5 to 1.5, preferably from 1 to 1.5, very preferably from 1.2 to 1.5 (where x=1.5 Al₂O₃).

The layer thickness is 5 to 300 nm, preferably 10 to 100 nm, more preferably 20 to 80 nm.

The inorganic oxides may be applied by means of physical vacuum deposition (electron-beam or thermal process), magnetron sputtering or chemical vacuum deposition. This may take place reactively (with supply of oxygen) or non-reactively. A flame, plasma or corona pretreatment is likewise possible.

### Adhesive Layer2

The adhesion between the inorganic layers with adhesive layer2 is achieved preferably with a 2-component polyurethane-based adhesive (2K-PU adhesive) which is optimized for inorganic layers. The layer thickness of adhesive2 is 0.1 to 10 μm, preferably 0.5 to 5 μm, more preferably 0.5 to 1 μm.

Furthermore, adhesive layer2 optionally comprises a component which improves the adhesion to SiOx, examples being acrylates or methacrylates containing siloxane groups, e.g. methacryloyloxypropyltrimethoxysilane. The amount of acrylates or methacrylates containing siloxane groups in the adhesive layer may be 0% to 48% by weight. The adhesive layer contains 0.1% to 10% by weight, preferably 0.5% to 5% by weight, more preferably 1% to 3% by weight, of initiator, e.g. Irgacure® 184 or Irgacure® 651. As chain transfer agents, the adhesive layer may also contain 0% to 10% by weight, preferably 0.1% to 10% by weight, more preferably 0.5% to 5% by weight, of sulphur compounds. In one variant, part of the main component is replaced by 0% to 30% by weight of prepolymer. The adhesive component optionally comprises 0% to 40% by weight of additives that are customary for adhesives.

It is also possible to use UV/Vis-curing systems based on epoxy, such as DELO KATIOBOND LP655, LP VE19781 or LP VE19663, for example, which additionally improve the barrier effect.

### Adhesive Layer2a

Adhesive2a is used to join inorganic oxide layers alternatively directly to the polymer film, preferably to a PET or polyolefin film. Depending on the combination of materials, adhesive2a may correspond to an adhesive2 or an adhesive3.

### Adhesive Layer3

The PET films, or polyester or polyolefin films, may be joined to one another by means of a 2K-PU adhesive, by a melt adhesive, based on EVA or acrylate-ethylene, for example, or by extrusion lamination. In the latter case, the adhesive3 layers are done away with. Alternatively, a PET film may also be coated on both sides with SiOₓ. Alternatively it is also possible to employ the systems described under adhesive4.

Adhesive layer3 has a thickness of 1 to 100 μm, preferably of 2 to 50 μm, more preferably of 5 to 20 μm.

### Adhesive Layer4

Adhesive layer4 is situated between support laminate and barrier layer. It allows adhesion between the two. The adhesive layer has a thickness of 1 to 100 μm, preferably of 2 to 50 μm, more preferably of 5 to 20 μm. Adhesive layer4 may be identical with adhesive layer3 in terms of its composition and thickness.

Adhesive layer4 may be formed of a melt adhesive. This melt adhesive may comprise polyamides, polyolefins, thermoplastic elastomers (polyester, polyurethane or copolyamide elastomers) or copolymers. Preference is given to ethylene-vinyl acetate copolymers or ethylene-acrylate or ethylene-methacrylate copolymers. The adhesive layer may be applied by means of roll application methods in lamination, or by means of a nozzle in extrusion lamination or in extrusion coating.

### Adhesive Layer5

The film laminate may be adhered to a substrate by means of an adhesive layer comprising adhesive5, which is applied to the bottom side, i.e. to the side of the barrier laminate that is facing away from the support laminate. The substrate may be, for example, a semiconductor such as silicon. The adhesive in this case may be a hotmelt such as an ethylene-vinyl acetate EVA, for example. The hotmelt layers generally have a thickness of between 50 and 500 μm.

### Applications

This barrier film may be used in the packaging industry, in display technology, in organic photovoltaics, in thin-film photovoltaics, in crystalline silicon modules, and for organic LEDs.

### WORKING EXAMPLES

A polymer film (e.g. PET) is coated with a barrier layer (e.g. SiOₓ). This is joined to a second SiOx-coated polymer film by roll application methods, by means of an adhesive layer2, in such a way that the SiOx layers are facing one another. The resulting barrier assembly is joined by means of a pressure-sensitive adhesive to a second barrier assembly, by lamination. The support laminate, produced by coextrusion of PMMA, hotmelt and PP, is applied to the resulting film assembly. As adhesive layer4 for the lamination it is possible, for example, to use a polyurethane-based adhesion promoter. This may be applied by roll application methods (roll coating or kiss coating).

### Example 1

Protective layer: coextrudate of PVDF (layer thickness: 10 μm) and im-PMMA (layer thickness: 50 μm)

Adhesive layer1: Admer AT 1955 (layer thickness: 50 μm)

Support film: PE Dowlex 2108G (layer thickness: 180 μm)

Adhesive layer4: two-component system Liofol LA 2692-21 and hardener UR 7395-22 from Henkel

Polymer film including barrier layer: Alcan Ceramis (layer thickness 12 μm)

Adhesive layer2: DELO KATIOBOND LP655 (layer thickness: 1 μm)

The barrier assembly consisting of polymer film, barrier layer and adhesive layer2 is laminated to a second barrier assembly.

Adhesive layer3: identical with adhesive layer4

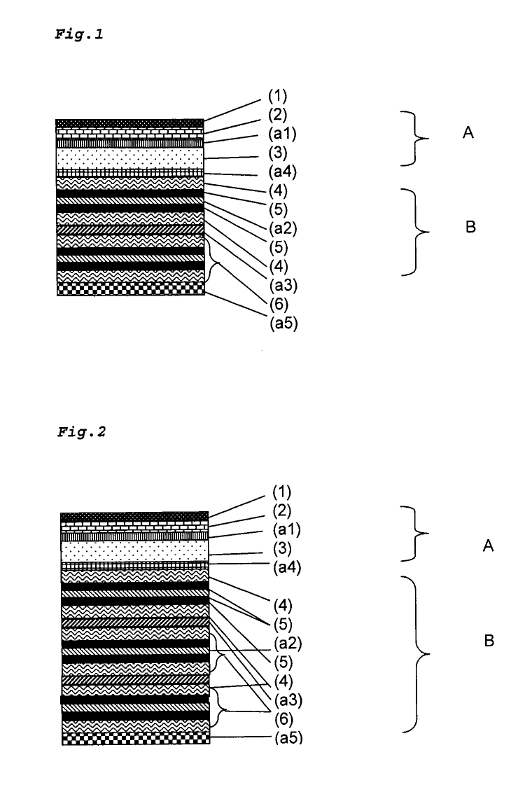

Construction: see FIG. 1

### Example 2

Scratch resistant coating: CRYSTALCOAT™ MP-100 (layer thickness: 10 μm)

Protective layer: im-PMMA (layer thickness: 50 μm)

Adhesive layer1: Bynel 22E780 (layer thickness: 40 μm)

Support film: PP Clyrell RC124H (layer thickness: 200 μm)

Adhesive layer4: 62% Laromer UA 9048 V, 31% hexanediol diacrylate, 2% hydroxyethyl methacrylate, 3% Irgacure 184, 2% butyl acrylate (layer thickness: 10 μm)

Polymer film: biaxially oriented PET (Hostaphan RNK layer thickness 12 μm)

Barrier layer: SiO_{1.5}

Adhesive layer2: 60% Laromer UA 9048 V, 30% hexanediol diacrylate, 2% hydroxyethyl methacrylate, 3% Irgacure 184, 2% butyl acrylate, 4% methacryloyloxypropyltrimethoxysilane (layer thickness: 1 μm)

Adhesive layer3: identical with adhesive layer4

Adhesive layer5: EVA Vistasolar 486.00 from Etimex (layer thickness: 200 μm)

Construction: see FIG. 2

### Example 3

Scratch resistant coating: UVHC3000K (layer thickness: 15 μm)

Protective layer: im-PMMA (layer thickness: 70 μm)

Adhesive layer1: Bynel 22E780 (layer thickness: 30 μm)

Support film: PET Tritan FX100 from Eastman (layer thickness: 180 μm)

Adhesive layer4: two-component system Liofol LA 2692-21 and hardener UR 7395-22 from Henkel

Polymer film: biaxially oriented PET (Hostaphan RNK, layer thickness 12 μm)

Barrier layer: Al₂O₃

Adhesive layer2: DELO KATIOBOND LP VE19663 (layer thickness: 0.8 μm)

The barrier assembly consisting of polymer film, barrier layer and adhesive layer2 is laminated first to a second barrier assembly and then to a third barrier assembly.

Adhesive layer3: identical with adhesive layer4

### Measurement of Barrier Properties

The water vapour permeability of the film system is measured in accordance with ASTM F-1249 at 23° C./85% relative humidity.

The partial discharge voltage is measured in accordance with DIN 61730-1 and IEC 60664-1 or DIN EN 60664-1.

### Comparative Example

A film according to the prior art (EP 1 018 166 B1), e.g. SiOx-coated ETFE, with a layer thickness of 50 μm, has a water vapour permeability of 0.7 g/(m² d).

An inventive film with 4 barrier assemblies has a water vapour permeation rate of less than 0.01 g/(m² d) (see Example 3).

The % figures in the examples always denote % by weight.

### LIST OF REFERENCE SYMBOLS FOR DRAWINGS

A Support laminate

B Sum of the barrier laminates

(1) Scratch-resistant coating

(2) Protective layer

(3) Support film

(4) Polymer film

(5) Barrier layer

(6) Repeated barrier laminate

(a1) Adhesive layer1

(a2) Adhesive layer2

(a3) Adhesive layer3

(a4) Adhesive layer4

(a5) Adhesive layer5

1. A film laminate, comprising:
a) a weathering-stable support laminate comprising, from outside to inside, a PMMA protective layer, a first adhesive layer and a support film;
b) a second adhesive layer; and
c) a barrier laminate comprising at least three inorganic oxide layers which improve the barrier effect to water vapour and oxygen.

2. The film laminate according to claim 1, wherein the first adhesive layer is an ethylene-acrylate hotmelt and the support film is a polyester film or polyolefin film.

3. The film laminate according to claim 1, wherein:
the support film has a thickness of between 100 and 400 μm;
the first adhesive layer has a thickness of between 20 and 80 μm; and
the PMMA protective layer has a thickness of between 50 and 400 μm.

4. The film laminate according to claim 1, wherein the PMMA protective layer has a scratch-resistant coating.

5. The film laminate according to claim 1, wherein the barrier laminate comprises at least three polymer films, at least three inorganic oxide layers and at least two adhesive layers comprising a third adhesive layer, a fourth adhesive layer, or both.

6. The film laminate according to claim 5, wherein the polymer films are polyester films or polyolefin films having a thickness of between 5 and 50 μm.

7. The film laminate according to claim 1, wherein:
the inorganic oxide layers are SiOₓ layers having an x value of between 1.3 and 1.7;
the inorganic oxide layers each have a thickness of between 10 and 100 nm.

8. The film laminate according to claim 1, wherein:
the inorganic oxide layers are AlOₓ layers having an x value of between 1.2 and 1.5;
the inorganic oxide layers each have a thickness of between 10 and 100 nm.

9. The film laminate according to claim 1, wherein the barrier laminate has the construction:
PET-SiOₓ-third adhesive layer-SiOₓ-PET-fourth adhesive layer-PET-SiOₓ-third adhesive layer-SiOₓ-PET;
PET-SiOₓ-third adhesive layer-SiOₓ-PET-fourth adhesive layer-PET-SiOₓ-third adhesive layer-SiOₓ-PET-fourth adhesive layer-PET-SiOₓ-third adhesive layer-SiOₓ-PET; or
PET-SiOₓ-third adhesive layer-SiOₓ-PET-SiOₓ-third adhesive layer-SiOₓ-PET.

10. The film laminate according to claim 1, wherein:
the film laminate comprises, from outside to inside, the weathering-stable support laminate, the second adhesive layer, the barrier laminate, and a third adhesive layer applied on the bottom side of the barrier laminate.

11. The film laminate according to claim 1, having a partial discharge voltage of at least 1000 V and a transparency of more than 80% in the range of more than 300 nm.

12. A process for producing the film liminate according to claim 1, the process comprising:
a) inorganically coating a polymer film by vacuum evaporation or sputtering, said polymer film being joined by an adhesive layer to at least two further inorganically coated films, and combining a resulting barrier laminate with the weathering-resistant support film by laminating, extrusion laminating or by extrusion coating, wherein the first adhesive layer is an ethylene-acrylate hotmelt and the support film is a polyester film or polyolefin film; or
b) inorganically coating a polymer film on both sides by vacuum evaporation or sputtering, said polymer film being joined by an adhesive layer to at least one further inorganically coated film, and combining a resulting barrier laminate with the weathering-resistant support film according by laminating, extrusion laminating or by extrusion coating, wherein the first adhesive layer is an ethylene-acrylate hotmelt and the support film is a polyester film or polyolefin film; or
c) inorganically coating a polymer film by vacuum evaporation or sputtering on both sides, said polymer film being joined by an adhesive layer to at least one further double-sidedly inorganically coated film, and combining a resulting film assembly with the weathering-resistant support film by extrusion coating, wherein the first adhesive layer is an ethylene-acrylate hotmelt and the support film is a polyester film or polyolefin film,
wherein:
in the physical vacuum evaporation of a) to c), silicon oxide or aluminium oxide is evaporated by an electron beam; or
in the physical vacuum evaporation of a) to c), silicon oxide or aluminium oxide is evaporated thermally.

13. An article, comprising the film laminate according to claim 1 which is suitable for the packaging industry, in display technology, and for organic LEDs.

14. An article, comprising the film laminate according to claim 1, said article selected from the group consisting of an organic photovoltaic, a thin-film photovoltaic, and a crystalline silicon module.

15. The film laminate according to claim 2, wherein:
the support film has a thickness of between 100 and 400 μm;
the first adhesive layer has a thickness of between 20 and 80 μm; and
the PMMA protective layer has a thickness of between 50 and 400 μm.

16. The film laminate according to claim 2, wherein the PMMA protective layer has a scratch-resistant coating.

17. The film laminate according to claim 2, wherein:
the inorganic oxide layers are SiOₓ layers having an x value of between 1.3 and 1.7;
the inorganic oxide layers each have a thickness of between 10 and 100 nm.

18. The film laminate according to claim 2, wherein:
the inorganic oxide layers are AlOₓ layers having an x value of between 1.2 and 1.5;
the inorganic oxide layers each have a thickness of between 10 and 100 nm.
